(19) United States
(12) Patent Application Publication
(10) Pub. No.: US 2012/0211263 A1
(43) Pub. Date: Aug. 23, 2012

(54) WIRED CIRCUIT BOARD AND PRODUCING METHOD THEREOF

(75) Inventor: Masaki MIZUTANI, Osaka (JP)

(73) Assignee: NITTO DENKO CORPORATION, Osaka (JP)

(21) Appl. No.: 13/365,978

(22) Filed: Feb. 3, 2012

Related U.S. Application Data
(60) Provisional application No. 61/457,336, filed on Mar. 3, 2011.

(30) Foreign Application Priority Data
Feb. 21, 2011 (JP) 2011-034446

(51) Int. Cl. H05K 1/00; H05K 3/10

(52) U.S. Cl. 174/250; 29/846

(57) ABSTRACT

A wired circuit board includes an insulating layer formed with an insulating opening extending through the insulating layer in a thickness direction, and a conductive pattern including a wire formed on the insulating layer and a terminal connected to the wire. The terminal includes a filling portion with which the insulating opening of the insulating layer is internally filled, a first projecting portion formed to continue to the filling portion and project from the filling portion on one side in the thickness direction, and a second projecting portion formed to continue to the filling portion and project from the filling portion on the other side in the thickness direction.

### CROSS-REFERENCE TO RELATED APPLICATION

The present application claims the benefit of U.S. Provisional Application No. 61/457,336 filed on Mar. 3, 2011, and claims priority from Japanese Patent Applications No. 2011-034446 filed on Feb. 21, 2011, the contents of which are hereby incorporated by reference into this application.

### BACKGROUND OF THE. INVENTION

1. Field of the Invention

The present invention relates to a wired circuit board and a producing method thereof, and particularly to a wired circuit board subjected to an electrical continuity test and a producing method thereof.

2. Description of the Related Art

A wired circuit board such as a suspension board with circuit includes a conductive pattern. After subjected to an electrical continuity test, the conductive pattern is electrically connected to a magnetic head and an external board.

Such a suspension board with circuit includes a metal supporting board, an insulating base layer formed thereon, a conductive pattern formed thereon, and an insulating cover layer covering the conductive pattern. The conductive pattern includes terminals and wires connected thereto. In such a suspension board with circuit, testing probes for the electrical continuity test are connected first to the terminals, and then connection terminals of a magnetic head or an external board are electrically connected to the terminals.

Specifically, it has been proposed to fill openings in an insulating base layer with terminals such that the terminals downwardly fit into the openings in the insulating base layer, expose the back surfaces of the filling terminals from a supporting board, and form the surfaces of the terminals as flying leads exposed from an insulating cover layer (see, e.g., Japanese Unexamined Patent No. 2005-337811).

In Japanese Unexamined Patent No. 2005-337811, a testing probe is brought into contact with the back surface of each of the terminals to test electrical continuity of a conductive pattern including the terminals. Then, connection terminals of a control circuit board are brought into contact with the surfaces of the terminals to provide electrical connection therebetween.

In Japanese Unexamined Patent No. 2005-337811, it may also be possible to reverse the respective vertical positions of the testing probe and the control circuit board and achieve electrical connection between the terminals and each of the testing probe and the control circuit board.

### SUMMARY OF THE INVENTION

However, when the connection terminals of the control circuit board are to be brought into contact, from above, with the surfaces of the terminals of the suspension board with circuit of Japanese Unexamined Patent No. 2005-337811, it is difficult to bring the connection terminals of the control circuit board into contact with the surfaces of the terminals since the terminals have downwardly fitted into the openings in the insulating base layer. As a result, electrical connection may not be able to be reliably achieved between the connection terminals of the control circuit board and the terminals of the suspension board with circuit. This results in the problem of degraded connection reliability between the conductive pattern and the control circuit board.

Also, in the case where the respective vertical positions of the testing probe and the control circuit board are reversed, when the testing probe is to be brought into contact, from above, with the surface of each of the terminals, it is difficult to bring the testing probe into contact with the surface of each of the terminals since the terminals have downwardly fitted into the openings in the insulating base layer. As a result, electrical connection may not be able to be reliably achieved between the testing probe and each of the terminals of the suspension board with circuit. This results in the problem that an electrical continuity test using the testing probe cannot be reliably performed.

It is therefore an object of the present invention to provide a wired circuit board which allows an electrical continuity test to be reliably performed and has excellent connection reliability and a producing method thereof.

A wired circuit board of the present invention includes an insulating layer formed with an insulating opening extending through the insulating layer in a thickness direction, and a conductive pattern including a wire formed on the insulating layer and a terminal connected to the wire, wherein the terminal includes a filling portion with which the insulating opening of the insulating layer is internally filled, a first projecting portion formed to continue to the filling portion and project from the filling portion to one side in the thickness direction, and a second projecting portion formed to continue to the filling portion and project from the filling portion to the other side in the thickness direction.

In the wired circuit board of the present invention, it is preferable that the first projecting portion continues to the wire.

A method of producing a wired circuit board of the present invention includes the steps of forming an insulating layer formed with an insulating opening extending through the insulating layer in a thickness direction, and forming a conductive pattern including a wire formed on the insulating layer and a terminal connected to the wire, wherein, in the step of forming the conductive pattern, the conductive pattern is formed such that the terminal includes a filling portion with which the insulating opening of the insulating layer is internally filled, a first projecting portion formed to continue to the filling portion and project from the filling portion to one side in the thickness direction, and a second projecting portion formed to continue to the filling portion and project from the filling portion to the other side in the thickness direction.

In the wired circuit board of the present invention obtained by the method of producing the wired circuit board of the present invention, the terminal includes the filling portion, the first projecting portion, and the second projecting portion. Therefore, if the probe of a testing device is brought closer to either of the first projecting portion and the second projecting portion, the probe can be reliably brought into contact with either of the first projecting portion and the second projecting portion, while a connection terminal can also be reliably brought into contact with the other projecting portion.

This can ensure both the achievement of electrical connection between the terminal and the probe and the achievement of electrical connection between the terminal and the connection terminal of an external board.

As a result, it is possible to improve the connection reliability of the conductive pattern, while reliably performing an electrical continuity test on the conductive pattern.

### BRIEF DESCRIPTION OF THE DRAWINGS

FIG. 1 is a plan view of a suspension board with circuit as an embodiment of a wired circuit board of the present invention;

FIG. 2 is an enlarged plan view of the rear end portion of the suspension board with circuit shown in FIG. 1;

FIG. 3 is an enlarged bottom view of the rear end portion of the suspension board with circuit shown in FIG. 1;

FIG. 4 is a cross-sectional view of the rear end portion of the suspension board with circuit shown in FIG. 1, which is taken along the line A-A of FIG. 2;

FIG. 5 is a cross-sectional view of the rear end portion of the suspension board with circuit shown in FIG. 1, which is taken along the line B-B of FIG. 2;

FIG. 6 is a process view for illustrating a producing method of the suspension board with circuit shown in FIG. 1,

(a) showing the step of preparing a metal supporting board,

(b) showing the step of forming an insulating base layer,

(c) showing the step of forming a support opening in the metal supporting board,

(d) showing the step of forming a conductive pattern,

(e) showing the step of forming an insulating cover layer, and

(f) showing the step of laminating a plating layer;

FIG. 7 is a process view for illustrating the step of forming the conductive pattern of FIG. 6(d),

(a) showing the step of forming a seed film.,

(b) showing the step of forming a plating resist,

(c) showing the step of forming the conductive pattern by plating, and

(d) showing the step of removing the plating resist and the portion of the seed film where the plating resist is laminated;

FIG. 8 is a cross-sectional view of the rear end portion of the suspension board with circuit shown in FIG. 1, which is taken along the line A-A of FIG. 2,

(a) showing the step of connecting probes to first projecting portions, and

(b) showing the step of connecting connection terminals of an external board to second projecting portions;

FIG. 9 is a cross-sectional view of the rear end portion of the suspension board with circuit shown in FIG. 1, which is taken along the line B-B of FIG. 2,

(a) showing the step of connecting the probes to the first projecting portions, and

(b) showing the step of connecting the connection terminals of the external board to the second projecting portions; and

FIG. 10 is a process view for illustrating a producing method of a suspension board with circuit of Comparative Example 1,

(a) showing the step of preparing a metal supporting board,

(b) showing the step of forming an insulating base layer,

(c) showing the step of forming a conductive pattern,

(d) showing the step of forming a support opening in the metal supporting board,

(e) showing the step of forming an insulating cover layer, and

(f) showing the step of laminating a plating layer.

### DETAILED DESCRIPTION OF THE INVENTION

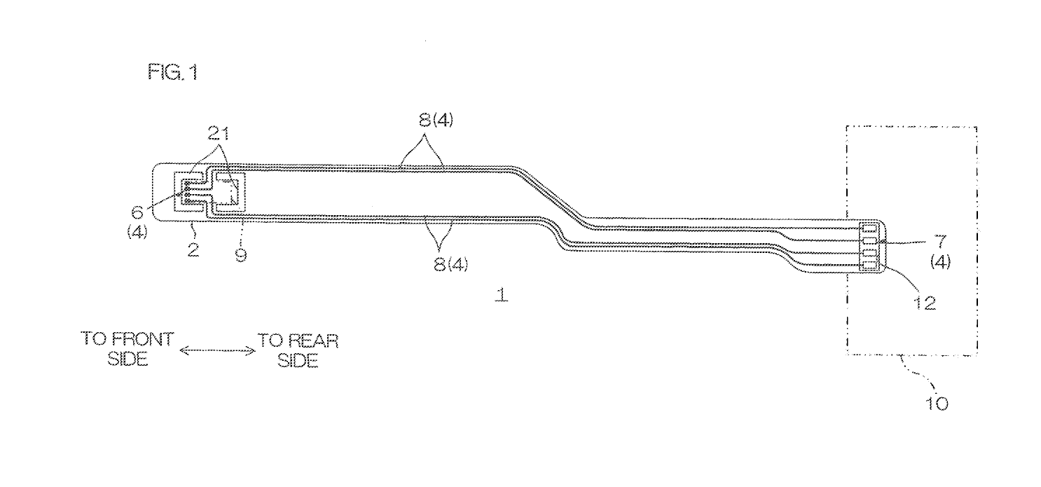

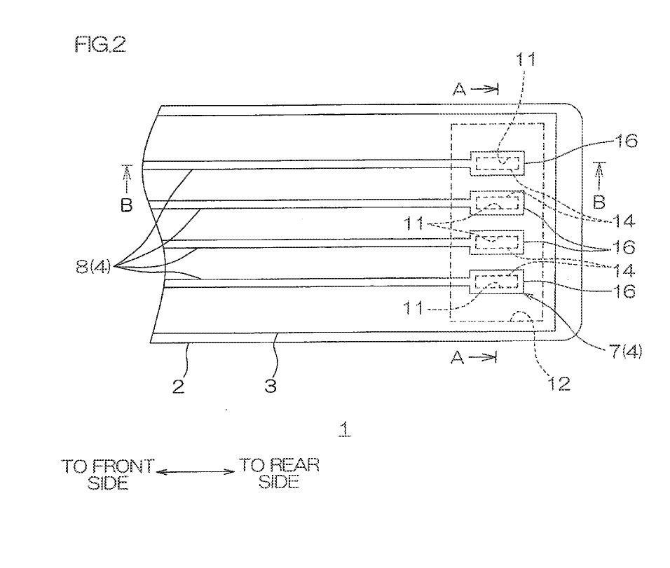

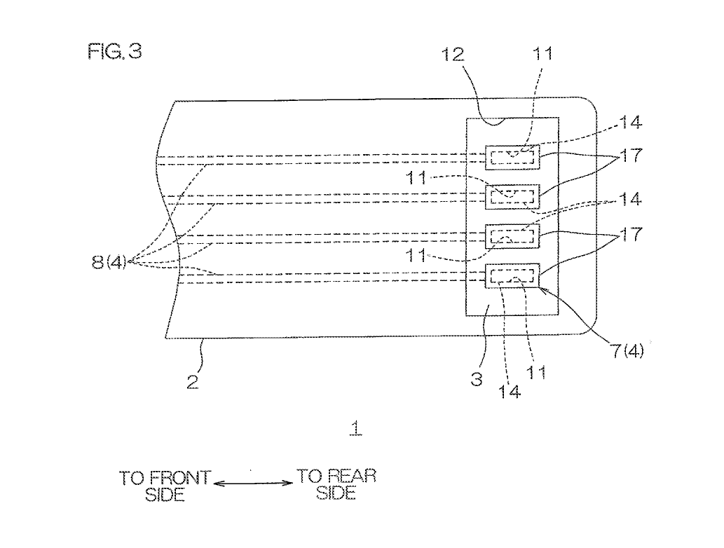

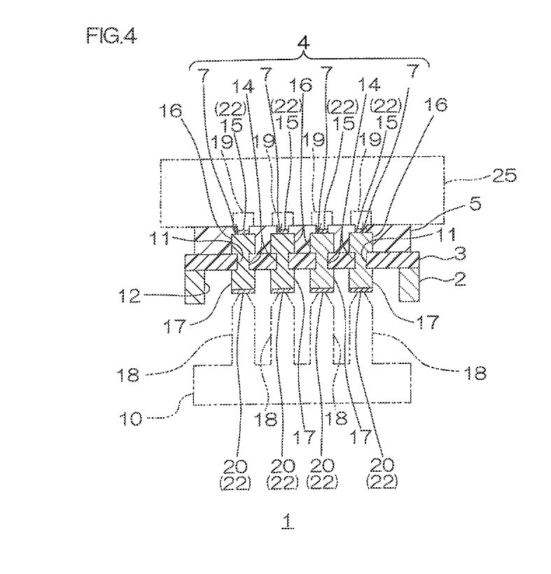

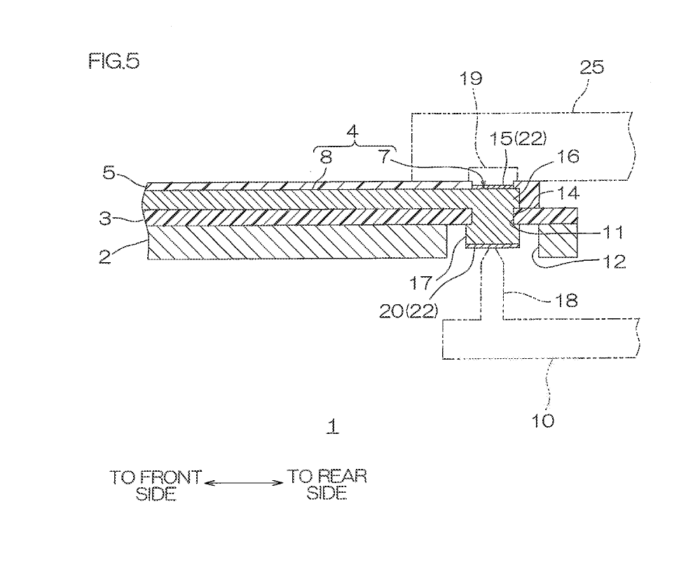

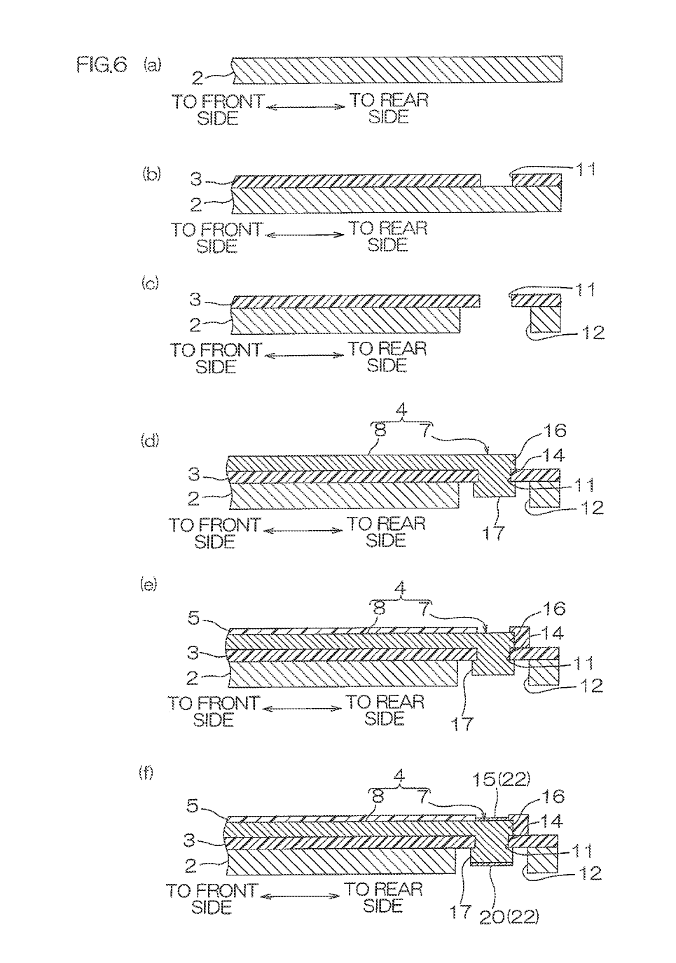

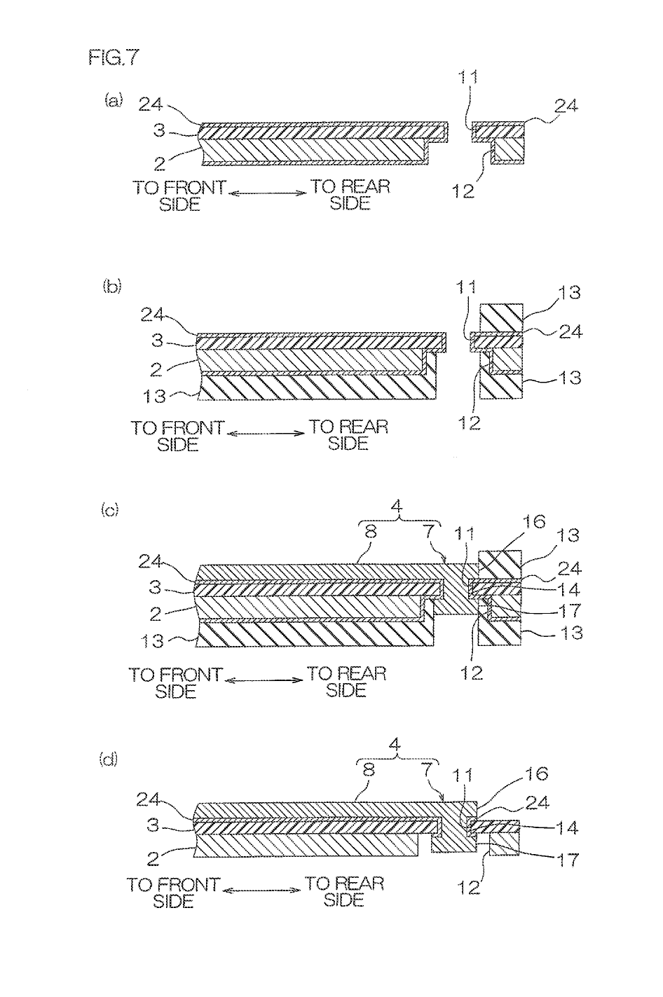

FIG. 1 is a plan view of a suspension board with circuit as an embodiment of a wired circuit board of the present invention. FIG. 2 is an enlarged plan view of the rear end portion of the suspension board with circuit shown in FIG. 1. FIG. 3 is an enlarged bottom view of the rear end portion of the suspension board with circuit shown in FIG. 1. FIG. 4 is a cross-sectional view of the rear end portion of the suspension board with circuit shown in FIG. 1, which is taken along the line A-A of FIG. 2. FIG. 5 is a cross-sectional view of the rear end portion of the suspension board with circuit shown in FIG. 1, which is taken along the line B-B of FIG. 2. FIG. 6 is a process view for illustrating a producing method of the suspension board with circuit shown in FIG. 1. FIG. 7 is a process view for illustrating the step of forming the conductive pattern of FIG. 6(d).

Note that, in FIGS. 1 and 2, insulating cover layer 5 is omitted for clear illustration of relative positioning of a conductive pattern 4. Also, in FIG. 1, an insulating base layer 3 is omitted for clear illustration of relative positioning of the conductive pattern 4. Also, in FIGS. 2 and 3, plating layers 22 are omitted for clear illustration of relative positioning of external terminals 7.

In FIG. 1, the suspension board with circuit 1 on which a slider 9 (imaginary line) having a magnetic head mounted thereon and an external board 25 (see the imaginary lines of FIGS. 4 and 5) are mounted is mounted on a hard disk drive.

The suspension board with circuit 1 is formed in a flat belt shape extending in a longitudinal direction, and includes a metal supporting board 2 and the conductive pattern 4 supported thereon.

The metal supporting board 2 is formed in a shape corresponding to a plan shape of the suspension board with circuit 1.

In a front end portion (one longitudinal end portion) of the metal supporting board 2, slits 21 are formed so as to extend through the metal supporting board 2 in a thickness direction. The slits 21 are located to be spaced apart from each other in a front-rear direction.

In the rear end portion (the other longitudinal end portion) of the metal supporting board 2, a support opening 12 is formed so as to extend therethrough in the thickness direction. The support opening 12 is formed in a generally rectangular plan view shape elongated in a widthwise direction (direction perpendicular to the front-rear direction).

The conductive pattern 4 integrally includes head-side terminals 6 formed on the front end portion of the metal supporting board 2, the external terminals 7 as terminals formed on the rear end portion of the metal supporting board 2, and wires 8 electrically connecting the head-side terminals 6 and the external terminals 7.

The head-side terminals 6 are disposed so as to be interposed between the slits 21 in the front-rear direction.

The external terminals 7 are disposed so as to be surrounded by the support opening 12 of the metal supporting board 2 when projected in the thickness direction.

As shown in FIGS. 4 and 5, the suspension board with circuit 1 includes the metal supporting board 2, the insulating base layer 3 as an insulating layer formed on the metal supporting board 2, the conductive pattern 4 formed on the insulating base layer 3, and the insulating cover layer 5 formed on the insulating base layer 3 so as to cover the conductive pattern 4.

Examples of a metal material for forming the metal supporting board 2 include stainless steel, a 42-alloy, aluminum, a copper-beryllium alloy, or phosphor bronze. Preferably, stainless steel is used.

The thickness of the metal supporting board 2 is in a range of, e.g., 10 to 50 μm, or preferably 12 to 30 μm.

The insulating base layer 3 is formed on the upper surface of the metal supporting board 2 into a pattern corresponding to the conductive pattern 4. In the insulating base layer 3, base openings 11 as insulating openings extending through the rear end portion thereof in the thickness direction are formed so as to correspond to the external terminals 7.

Examples of an insulating material for forming the insulating base layer 3 include synthetic resins such as a polyimide resin, a polyamideimide resin, an acrylic resin, a polyether nitrile resin, a polyether sulfone resin, a polyethylene terephthalate resin, a polyethylene naphthalate resin, and a polyvinyl chloride resin. Preferably, a polyimide resin is used.

The thickness of the insulating base layer 3 is in a range of e.g., 1 to 35 μm, or preferably 3 to 33 μm.

The conductive pattern 4 is formed as a wired circuit pattern including the head-side terminals 6 (see FIG. 1) described above, the external terminals 7, and the wires 8.

As shown in FIG. 1, the plurality of head-side terminals 6 are arranged in widthwise aligned and spaced-apart relation on the insulating base layer (see FIGS. 2 and 5). Each of the head-side terminals 6 is formed in a generally rectangular plan view shape elongated in the front-rear direction.

As shown in FIG. 2, the plurality of external terminals 7 are arranged in widthwise aligned and spaced-apart relation on the insulating base layer 3 (see FIGS. 4 and 5). Each of the external terminals 7 is formed in a generally rectangular plan view shape elongated in the front-rear direction.

As shown in FIG. 1, the wires 8 are formed on the insulating base layer (see FIGS. 2 and 5) so as continue to the rear end portions of the head-side terminals 6 and to the front end portions of the external terminals 7.

Examples of a conductive material for forming the conductive pattern 4 include copper, nickel, chromium, gold, a solder, or an alloy thereof. Preferably, copper is used.

The width (length in the widthwise direction) of each of the head-side terminals 6 is in a range of, e.g., 10 to 250 μm, or preferably 20 to 100 μm. The length (length in the front-rear direction) of each of the head-side terminals 6 is in a range of, e.g., 10 to 2060 μm, or preferably 20 to 560 μm. The spacing between the individual head-side terminals 6 is in a range of, e.g., 20 to 1000 μm, or preferably 30 to 800 μm.

The width of each of the wires 8 is in a range of, e.g., 5 to 200 μm, or preferably 8 to 100 μm. The spacing between the individual wires 8 is in a range of, e.g., 5 to 200 μm, or preferably 8 to 100 μm.

Note that the dimensions of the external terminals 7 are described later in detail.

The thickness of each of the wires 8 and the head-side terminals 6 is in a range of, e.g., 3 to 50 μm, or preferably 5 to 20 μm.

As shown in FIGS. 4 and 5, the insulating cover layer 5 is formed over the upper surface of the insulating base layer 3 exposed from the conductive pattern 4 and the upper surfaces and side surfaces (not shown in FIG. 5) of the wires 8. The insulating cover layer 5 is formed so as to expose the head-side terminals 6 and the external terminals 7.

As an insulating material for forming the insulating cover layer 5, the same insulating material as that for forming the insulating base layer can be used. The thickness of the insulating cover layer 5 is in a range of, e.g., 2 to 20 μm, or preferably 4 to 15 μm.

Next, the rear end portion of the suspension board with circuit 1 is described in detail with reference to FIGS. 2 to 5.

As shown in FIG. 3, in the rear end portion of the suspension board with circuit 1, the support opening 12 is formed in the metal supporting board 2. The support opening 12 is formed to include the base openings 11 when projected in the thickness direction.

The base openings 11 are surrounded by the support opening 12 when projected in the thickness direction. The plurality of base openings 11 are each formed in a generally rectangular plan view shape elongated in the front-rear direction correspondingly to the head-side terminals 6. The individual base openings 11 are arranged in widthwise aligned and spaced-apart relation.

The width of each of the base openings 11 is in a range of, e.g., 10 to 1000 μm, or preferably 30 to 600 μm. The length of each of the base openings 11 is in a range of, e.g., 40 to 2000 μm, or preferably 60 to 1000 μm. The spacing between the individual base openings 11 is in a range of, e.g., 20 to 1000 μm, or preferably 30 to 800 μm.

The external terminals 7 are formed to be included in the support opening 12 when projected in the thickness direction. As shown in FIGS. 4 and 5, each of the external terminals 7 includes a filling portion 14 with which each of the base openings 11 of the insulating base layer 3 is internally filled, a first projecting portion 16 formed so as to project upward (to one side in the thickness direction) from the filling portion 14, and a second projecting portion 17 formed to continue to the filling portion 14 and project downward (to the other side in the thickness direction) from the filling portion 14.

The filling portion 14 is formed in a shape corresponding to the base opening 11. The thickness of the filling portion 14 is the same as the thickness of the insulating base layer 3.

The first projecting portion 16 is formed to protrude upward from the upper portion of the filling portion 14, to both outsides in the widthwise direction, and to both outsides in the front-rear direction. Specifically, the first projecting portion 16 is formed to have the same shape as the plan view shape of the external terminal 7. More specifically, as shown in FIG. 2, the first projecting portion 16 is formed in a generally rectangular plan view shape elongated in the from-rear direction.

As shown in FIGS. 4 and 5, the lower surfaces of the peripheral end portions (both end portions in the front-rear direction and both end portions in the widthwise direction) of the protrusions of the first projecting portions 16 are in contact with the upper surface of the insulating base layer 3 around the base openings 11.

The middle portions of the lower portions of the first projecting portions 16 continue to the upper portions of the filling portions 14. This allows the individual first projecting portions 16 to be electrically connected to the respective filling portions 14.

The rear side surfaces of the first projecting portions 16, the both widthwise side surfaces thereof, and the peripheral end portions of the upper surfaces thereof are covered with the insulating cover layer 5.

On the other hand, the front end portions of the first projecting portions 16 continue to the rear end portions of the wires 8. This allows the first projecting portions 16 to be electrically connected to the wires 8.

Also, as shown in FIG. 5, the upper surfaces of the first projecting portions 16 are formed to be flush with the upper surfaces of the wires 8 in the front-rear direction.

Of the external terminals 7, the portions corresponding to the thickness of the wire 8 are formed into the first projecting portions 16.

The middle portions of the upper surfaces of the first projecting portions 16 are exposed from the insulating cover layer 5.

The width of each of the first projecting portions 16 is in a range of, e.g., 10 to 250 μm, or preferably 20 to 100 μm. The length of each of the first projecting portions 16 is in a range of, e.g., 10 to 2060 μm, or preferably 20 to 560 μm. The spacing between the individual first projecting portions 16 is in a range of e.g., 20 to 1000 μm, or preferably 30 to 800 μm. The thickness of each of the first projecting portions 16 is the same as that of each of the wires 8 and the head-side terminals 6.

The second projecting portion 17 is formed to protrude downward from the lower portion of the filling portion 14, to both outsides in the widthwise direction, and to both outsides in the front-rear direction. Specifically, the second projecting portion 17 is formed to have the same shape as that of the first projecting portion 16 when projected in the thickness direction. That is, the second projecting portion 17 is formed to have the same shape as the bottom view shape of the head-side terminal 6. Specifically, as shown in FIG. 3, the second projecting portion 17 is formed in a generally rectangular bottom view shape elongated in the front-rear direction.

As shown in FIGS. 4 and 5, the upper surfaces of the peripheral end portions (both end portions in the front-rear direction and both end portions in the widthwise direction) of the protrusions of the second projecting portions 17 are in contact with the lower surface of the insulating base layer 3.

The middle portions of the upper portions of the second projecting portions 17 continue to the lower surfaces of the filling portions 14. This allows the individual second projecting portions 17 to be electrically connected to the respective filling portions 14.

Accordingly, the individual second projecting portions 17 are electrically connected to the respective first projecting portions 16 via the respective filling portions 14.

Also, the second projecting portions 17 are located in the support opening 12 of the metal supporting board 2 to be spaced apart therefrom. This electrically insulates the second projecting portions 17 from the metal supporting board 2 around (outside) the support opening 12.

The width of each of the second projecting portions 17, the length thereof, and the thickness thereof are the same as the width of each of the first projecting portions 16, the length thereof, and the thickness thereof. Also, the spacing between the individual second projecting portions 17 is the same as the spacing between the individual first projecting portions 16.

In the suspension board with circuit 1, on the surfaces of the external terminals 7, the plating layers 22 are laminated.

Each of the plating layers 22 includes a first plating layer 15 formed on the upper surface of the corresponding external terminal 7 and a second plating layer 20 formed on the lower surface of the corresponding external terminal 7.

The first plating layers 15 are laminated on the middle portions of the upper surfaces (surfaces) of the first projecting portions 16 exposed from the insulating cover layer 5.

Examples of a metal for forming the first plating layers 15 include conductive materials such as gold, nickel, chromium, and an alloy thereof. Preferably, gold is used. These metals can be used alone or in combination of two or more kinds.

The thickness of each of the first plating layers 15 is in a range of, e.g., 0.01 to 10 μm, or preferably 0.1 to 1 μm.

Note that the first plating layers 15 are also laminated on the surfaces (upper surfaces) of the head-side terminals 6 (see FIG. 1), though not shown in FIGS. 4 and 5.

The second plating layers 20 are laminated on the lower surfaces (surfaces) of the second projecting portions 17.

A metal for forming the second plating layers 20 is the same as the metal for forming the first plating layers 15. The thickness of each of the second plating layers 20 is the same as the thickness of the first plating layer 15.

Next, a producing method of the suspension board with circuit 1 is described with reference to FIGS. 6 and 7.

First, in the method, as shown in FIG. 6(a), a plate-like metal supporting board 2 is prepared.

Next, as shown in FIG. 6(b), the insulating base layer 3 is formed on the metal supporting board 2 such that the base openings 11 are formed therein.

To form the insulating base layer 3 in the foregoing pattern, e.g., a solution (varnish) of a photosensitive synthetic resin is coated on the metal supporting board 2 to form a photosensitive base coating. Then, the photosensitive base coating is exposed to light and developed into the foregoing pattern, which is subsequently cured by heating as necessary.

Then, as shown in FIG. 6(c), the support opening 12 is formed in the metal supporting board 2. The support opening 12 is formed so as to include the base openings 11 of the insulating base layer 3 when viewed in bottom view.

Specifically, to form the support opening 12, e.g., etching such as wet etching (such as, e.g., chemical etching) or dry etching (such as, e.g., laser processing), machining such as drilling perforation, or the like is used. Preferably, etching is used.

Next, as shown in FIG. 6(d), the conductive pattern 4 is formed in a pattern corresponding to the head-side terminals 6 (see FIG. 1), the external terminals 7, and the wires 8 each described above.

To form the conductive pattern 4, a known patterning method such as, e.g., an additive method or a subtractive method is used. Preferably, the additive method is used.

In the additive method, as shown in FIG. 7(a), a seed film 24 is formed first on the entire surface of the insulating base layer 3.

Specifically, the seed film 24 is formed on the entire upper surface of the insulating base layer 3, on the inner side surfaces of the base openings 11 of the insulating base layer 3, and the lower surface of the insulating base layer 3 exposed from the support opening 12 of the metal supporting board 2.

To form the seed film 24 on the entire surface of the insulating base layer 3, a thin film formation method such as physical vapor deposition such as, e.g., sputtering is used.

Specifically, by chromium sputtering and copper sputtering, a chromium thin film and a copper thin film are successively laminated over the entire surfaces of the insulating base layer 3 and the metal supporting board 2.

Note that, when formed by the thin-film formation method described above, the seed film 24 is formed on the entire surfaces of the metal supporting board 2 (specifically, on the lower surface of the metal supporting board 2, the inner side surface of the support opening 12 of the metal supporting board 2, and the upper surface of the metal supporting board 2 exposed from the insulating base layer 3).

The thickness of the seed film 24 is in a range of, e.g., 10 to 200 μm, or preferably 20 to 100 nm.

Next, in the additive method, as shown in FIG. 7(b), a plating resist 13 is formed in a pattern reverse to the conductive pattern 4 on the surface of the seed film 24.

That is, the plating resist film 13 is formed from a dry film resist into the foregoing pattern on each of the upper surface of the seed film 24 formed on the insulating base layer 3 and the lower surface of the seed film 24 formed under the metal supporting board 2 and the insulating base layer 3.

Next, in the additive method, as shown in FIG. 7(c), the conductive pattern 4 is formed on the surface of the seed film 24 exposed from the plating resist 13 by plating such as, e.g., electrolytic plating or electroless plating.

In the plating, the conductive material is inwardly precipitated from the surface (inner side surface) of the seed film 24 formed on each of the inner side surfaces of the base openings 11, and the precipitated portions internally fill the base openings 11 to form the filling portion 14.

At the same time, from the upper surface (surface) of the seed film 24 formed on the upper surface of the insulating base layer 3, the conductive material is upwardly precipitated, and the precipitated portions form the head-side terminals 6 (see FIG. 1), the wires 8, and the first projecting portions 16.

Meanwhile, in the support opening 12 of the metal supporting board 2, from the lower surface (surface) of the seed film 24 formed on the lower surface of the insulating base layer 3, the conductive material is downwardly precipitated, and the precipitated portions form the second projecting portions 17.

In this manner, the conductive pattern 4 is formed.

Then, in the additive method, as shown in FIG. 7(d), the plating resist 13 and the portion of the seed film 24 where the plating resist 13 is laminated are successively removed by, e.g., etching, stripping, or the like.

Note that, in FIG. 6(d), the seed film 24 formed in the case where the conductive pattern 4 is formed by the additive method is omitted.

Next, as shown in FIG. 6(e), the insulating cover layer 5 is formed on the insulating base layer 3 into a pattern covering the wires 8 and exposing the head side terminals 6 and the external terminals 7.

The insulating cover layer 5 is also formed into the pattern covering the peripheral end portions of the upper surfaces of the first projecting portions 16 of the external terminals 7 and exposing the middle portions of the upper surfaces of the first projecting portions 16.

To form the insulating cover layer 5, for example, a solution (varnish) of a photosensitive synthetic resin is coated on the metal supporting board 2, the insulating base layer 3, and the conductive pattern 4 to form a photosensitive cover coating. Then, the photosensitive cover coating is exposed to light and developed into the foregoing pattern, which is then cured by heating as necessary.

Next, as shown in FIG. 60), the plating layers 22 are laminated on the surfaces of the head-side terminals 6 (see FIG. 1) and the external terminals 7.

Specifically, the first plating layers 15 are laminated on the upper surfaces of the head-side terminals 6 (see FIG. 1) and the external terminals 7, while the second plating layers 20 are laminated on the lower surfaces of the external terminals 7.

More specifically, the first plating layers 15 are laminated on the middle portions of the upper surfaces of the first projecting portions 16 of the external terminals 7, while the second plating layers 20 are laminated on the lower surfaces of the second projecting portions 17 thereof.

The first plating layers 15 and the second plating layers 20 are simultaneously formed by plating such as, e.g., electroless plating or electrolytic plating.

Thereafter, as shown in FIG. 1, the slits 21 are formed in the metal supporting board 2, while the metal supporting board 2 is trimmed. For the formation of the slits 21 and the trimming of the metal supporting board 2, e.g., etching or the like is used.

In this manner, the suspension board with circuit 1 is obtained.

Thereafter, as shown by the imaginary line of FIG. 1, the slider 9 having the magnetic head mounted thereon is mounted on the obtained suspension board with circuit 1. In addition, the magnetic head is electrically connected to the head-side terminals 6.

Then, as shown by the imaginary line of FIG. 1, the electrical continuity of the conductive pattern 4 and the operation of the magnetic head are tested using a testing device 10.

Specifically, as shown by the imaginary lines of FIGS. 4 and 5, the testing device 10 is first disposed below the suspension board with circuit 1 such that the tips of probes 18 face upward.

Next, the probes 18 of the testing device 10 are brought closer to the second projecting portions 17 from below to come into contact with the lower surfaces of the second plating layers 20. Note that the tip surfaces (upper surfaces) of the probes 18 are formed smaller than the second projecting portions 17.

The probes 18 of the testing device 10 are electrically connected to the second projecting portions 17 via the second plating layers 20. In other words, the probes 18 are electrically connected to the conductive pattern 4.

Then, from the probes 18, test signals (test currents) are transmitted via the second plating layers 20 and the external terminals 7 to the wires 8, to the head-side terminals 6, and finally to the magnetic head. In this manner, the presence/absence of electrical continuity of the conductive pattern 4 and the normality/abnormality of the operation of the magnetic head are tested.

Thereafter, the probes 18 of the testing device 10 are moved apart from the second plating layers 20. Then, as shown by the imaginary lines of FIGS. 4 and 5, the external terminals 7 are electrically connected to connection terminals 19 of the external board 25 such as, e.g., a flexible wired circuit board.

Specifically, the external board 25 is disposed first above the external terminals 7 in facing relation such that the connection terminal 18 thereof face downward. Subsequently, the connection terminals 19 are brought closer to the first projecting portions 16 from above to come into contact with the upper surfaces of the external terminals 7.

In this manner, the connection terminals 19 are electrically connected to the first projecting portions 16 via the first plating layers 15. In other words, the connection terminals 18 are electrically connected to the conductive pattern 4.

In the suspension board with circuit 1, the external terminals 7 include the filling portions 14, the first projecting portions 16, and the second projecting portions 17. Therefore, if the probes 18 of the testing element 10 is brought closer to the second projecting portions 17, the probes 18 can be reliably brought into contact with the second projecting portions 17, while the connection terminals 19 of the external board 25 can also be reliably brought into contact with the first projecting portions 16.

This can ensure both the achievement of electrical connection between the external terminals 17 and the probes 18, and the achievement of electrical connection between the external terminals 7 and the connection terminals 19 of the external board 25.

As a result, it is possible to improve the connection reliability of the conductive pattern 4, while reliably testing the electrical continuity of the conductive pattern 4 and the operation of the magnetic head.

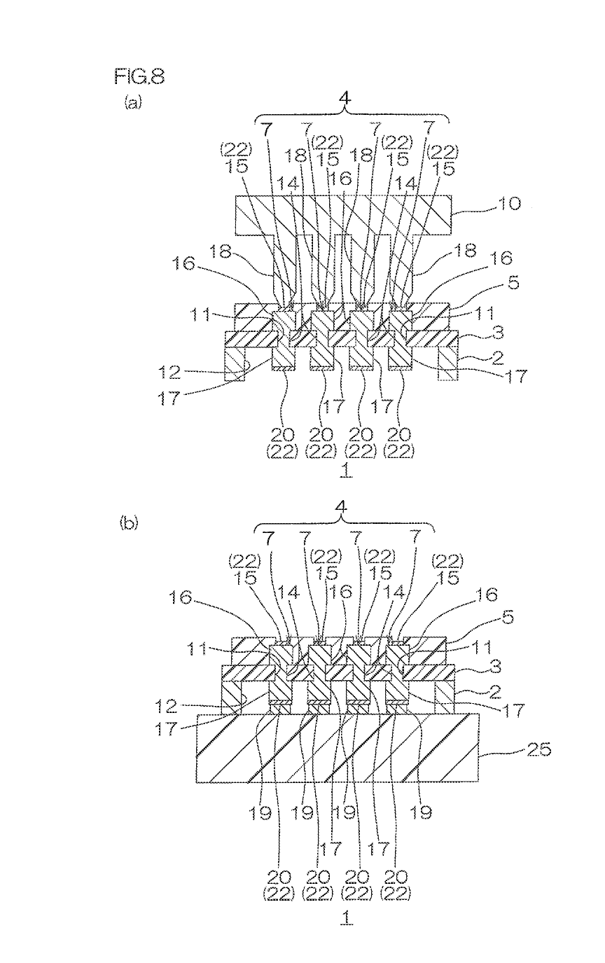

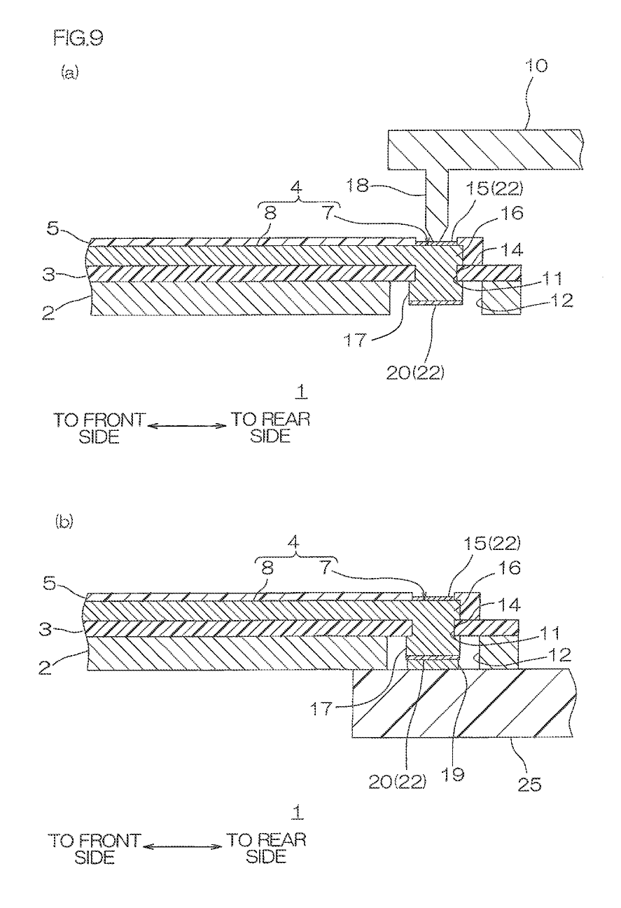

FIG. 8 is a cross-sectional view of the rear end portion of the suspension board with circuit shown in FIG. 1, which is taken along the line A-A of FIG. 2. FIG. 9 is a cross-sectional view of the rear end portion of the suspension board with circuit shown in FIG. 1, which is taken along the line B-B of FIG. 2.

Note that the members corresponding to the individual members described above are designated by the same reference numerals in each of the subsequent drawings, and a detailed description thereof is omitted.

In the embodiment shown by the imaginary lines of FIGS. 4 and 5, the testing device 10 is disposed below the external terminals 7 and the probes 18 are connected to the second projecting portions 17. Then, the external board 25 is disposed above the external terminals 7 and the connection terminals 19 are connected to the first projecting portions 17. However, as shown in, e.g., FIGS. 8 and 9, the respective vertical positions of the probes 18 and the external board 25 can also be reversed.

That is, as shown in FIGS. 8(a) and 9(a), by disposing the testing device 10 above the external terminals 7 and subsequently bringing, from above, the probes 18 closer to the first projecting portions 16 and into contact with the first plating layers 15, the probes 18 are brought into electrical contact with the first projecting portions 16 via the first plating layers 15.

Thereafter, as shown in FIGS. 8(b) and 9(a), by disposing the external board below the external terminals 7 and subsequently bringing, from below, the connection terminals 19 closer to the second projecting portions 17 and into contact with the second plating layers 20, the connection terminals 10 are brought into electrical contact with the second projecting portions 17 via the second plating layers 20.

According to the suspension board with circuit 1 shown in FIGS. 8 and 9, by bringing the probes 18 of the testing device 10 closer to the first projecting portions 16, the probes 18 can be reliably brought into contact with the first projecting portions 16, as shown in FIGS. 8(a) and 9(a), while the connection terminals 19 of the external board 25 can also be reliably brought into contact with the second projecting portions 17, as shown in FIGS. 8(b) and 9(b).

In the embodiment described above, the suspension board with circuit 1 in which the insulating base layer 3 is supported by the metal supporting board 2 is shown as an example of the wired circuit board of the present invention. However, the present invention is also widely applicable to various wired circuit boards such as, e.g., a flexible wired circuit board having the metal supporting board 2 provided as a reinforcing layer, a flexible wired circuit board not provided with the metal supporting board 2, and COF boards (including a TAB tape carrier and the like), though not shown.

### EXAMPLES

While in the following, the present invention is described more specifically with reference to Example and Comparative Example, the present invention is not limited to any of them.

### Example 1

A metal supporting board made of a stainless steel (SUS304) and having a thickness of 25 μm was prepared (see FIG. 6(a)).

Then, an insulating base layer was formed on the metal supporting board into a pattern formed with base openings each having a rectangular plan view shape (see FIG. 6(b)).

Specifically, onto the metal supporting board, a varnish of a photosensitive polyamic acid resin was coated to form a photosensitive base coating. Then, the photosensitive base coating was exposed to light and developed into the foregoing pattern, which was cured by heating.

The length of each of base openings was 150 μm, and the width thereof was 30 μm. The spacing between the individual base openings was 30 μm. The thickness of the insulating base layer was 20 μm.

Then, a support opening was formed by wet etching in the metal supporting board so as to have a rectangular bottom view shape and include the base openings of the insulating base layer (see FIG. 6(c)).

Then, a conductive pattern made of copper and including head-side terminals (see FIG. 1), external terminals, and wires was formed by an additive method (see FIG. 6(d)).

Specifically, a seed film including a chromium thin film having a thickness of 30 nm and a copper thin film having a thickness of 70 nm was laminated on the entire surfaces of the insulating base layer and the metal supporting board by successive chromium sputtering and copper sputtering (see FIG. 7(a)).

Then, on the surface of the seed film, a plating resist was formed from a dry film resist into a pattern reverse to the foregoing conductive pattern (see FIG. 7(b)).

Then, on the surface of the seed film exposed from the plating resist, a conductive pattern was formed by electrolytic copper plating (see FIG. 7(c)).

Specifically, in electrolytic copper plating, copper was inwardly precipitated from the inner side surface of the seed film formed on each of the inner side surfaces of the base openings. The precipitated portions of copper filled the base openings to form filling portions.

At the same time, from the upper surface of the seed film formed on the upper surface of the insulating base layer, copper was upwardly precipitated, and the precipitated portions of copper formed the head-side terminals (see FIG. 1), the wires, and first projecting portions.

Meanwhile, from the lower surface of the seed film formed on the lower surface of the insulating base layer, copper was downwardly precipitated, and the precipitated portions of copper formed second projecting portions.

In this manner, the conductive pattern integrally including the wires, the head-side terminals, the external terminals (filling portions, first projecting portions, and second projecting portions) was formed.

Note that the first projecting portions and the second projecting portions were each formed to have the same shape, i.e., a rectangular shape elongated in a front-rear direction when projected in a thickness direction.

The respective lengths of the first projecting portions and the second projecting portions were 200 μm, and the respective widths thereof were 40 μm. The respective spacings between the individual first projecting portions and between the individual second projecting portions were 40 μm.

Thereafter, the plating resist was removed by etching, and subsequently the portion of the seed film where the plating resist was laminated was removed by stripping (see FIG. 7(d)).

Then, the insulating cover layer was formed on the insulating base layer into a pattern covering the wires and exposing the head-side terminals and the external terminals (see FIG. 6(e)).

Specifically, onto the metal supporting board, the insulating base layer, and the conductive pattern, a varnish of a photosensitive polyamic acid resin was coated to form a photosensitive cover coating. Then, the cover coating was exposed to light and developed into the foregoing pattern, which was then cured by heating.

The thickness of the insulating cover layer was 5 μm.

Then, plating layers were laminated on the surfaces of the external terminals by electroless gold plating (see FIG. 6(f)).

Specifically, first plating layers made of gold were laminated on the upper surfaces of the head-side terminals and the external terminals, while second plating layers made of gold were laminated on the lower surfaces of the external terminals.

The respective thicknesses of the first plating layers and the second plating layers were 0.5 μm.

Thereafter, slits (see FIG. 1) were formed by etching in the metal supporting board, while the metal supporting board was trimmed, whereby a suspension board with circuit was obtained (see FIG. 1).

### Comparative Example 1

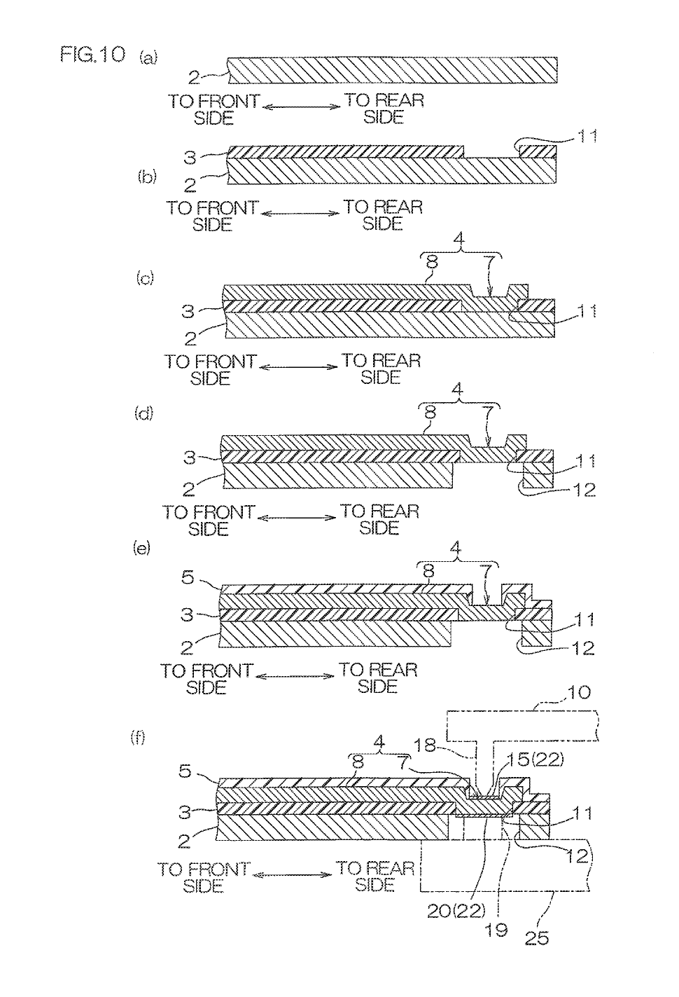

A suspension board with circuit was obtained in the same manner as in Example 1 except that, based on the description in Japanese Unexamined Patent No. 2005-337811, the external terminals were formed to downwardly fit into and fill the openings in the insulating base layer (see FIG. 10(f)).

That is, the step of forming the support opening was performed after the step of forming the conductive pattern.

The material, thickness, forming method, and so forth of each of the metal supporting board, the insulating base layer, the conductive pattern (except for the external terminals), and the insulating cover layer are substantially the same as in each of the steps of Example 1 described above.

Specifically, as shown in FIG. 10(a), the metal supporting board (2) was prepared first. Then, as shown in FIG. 10(b), on the metal supporting board (2), the insulating base layer (3) was formed into a pattern formed with the base openings (11).

Then, as shown in FIG. 10(c), the conductive pattern (4) was formed such that the external terminals (7) downwardly fit into and filled the base openings (11). Then, as shown in FIG. 10(d), the support opening (12) was formed in the metal supporting board (2) so as to expose the lower surfaces of the external terminals (7) with which the base openings (11) were filled.

Then, as shown in FIG. 10(e), the insulating cover layer (5) was formed on the insulating base layer (3) so as to expose the respective upper suffices of the head-side terminals (6) (see FIG. 1) and the external terminals (7).

Then, as shown in FIG. 10(f), the plating layers (20) were laminated on the surfaces of the head-side terminals (6) and the external terminals (7). Specifically, the first plating layers (15) were laminated on the upper surfaces of the head side terminals (6) and the external terminals (7), while the second plating layers (20) were laminated on the lower surfaces of the external terminals (7).

Thereafter, the slits (21) (see FIG. 1) were formed in the metal supporting board (2), while the metal supporting board (2) was trimmed, whereby the suspension board with circuit (1) was obtained (see FIG. 1).

(Evaluation)

(Electrical Continuity Test)

The conductive patterns of the suspension boards with circuit were each subjected to an electrical continuity test.

That is, by connecting the probes of a testing device to the external terminals, the electrical continuity test of each of the conductive patterns was performed. The details of the electrical continuity test are shown below.

### Evaluation of Example 1

A. Connection to Second Projecting Portions

In the suspension board with circuit of Example 1, the probes of the testing device were brought into contact with the second plating layers laminated on the surfaces of the second projecting portions of the external terminals (see FIGS. 4 and 5).

In this manner, the external terminals (second projecting portions) were electrically connected to the probes, and then the electrical continuity of the conductive pattern could be tested.

B. Connection to First Projecting Portions

Besides, the probes of the testing device were brought into contact with the first plating layers laminated on the first projecting portions of the external terminals (see FIGS. 8(a) and 8(a)).

In this manner, the external terminals (second projecting portions) were electrically connected to the probes, and then the electrical continuity of the conductive pattern could be tested.

### Evaluation of Comparative Example 1

A. Connection to Lower Surfaces of External Terminals

The probes of the testing device were brought into contact with the second plating layers laminated on the lower surfaces of the external terminals to electrically connect the probes to the external terminals. Then, the electrical continuity test of the conductive pattern could be tested.

B. Connection to Upper Surfaces of External Terminals

On the other hand, it was attempted to bring the probes of the testing device into contact with the first plating layers laminated on the upper surfaces of the external terminals. However, since the foregoing contact was insufficient, the probes could not be electrically connected to the external terminals. As a result, the electrical continuity test of the conductive pattern could not be performed.

While the illustrative embodiments of the present invention are provided in the above description, such is for illustrative purpose only and it is not to be construed restrictively. Modification and variation of the present invention that will be obvious to those skilled in the art is to be covered by the following claims.

What is claimed is:

1. A wired circuit board, comprising:
an insulating layer formed with an insulating opening extending through the insulating layer in a thickness direction; and
a conductive pattern, including a wire formed on the insulating layer and a terminal connected to the wire, wherein
the terminal includes:
a filling portion with which the insulating opening of the insulating layer is internally filled;
a first projecting portion formed to continue to the filling portion and project from the filling portion to one side in the thickness direction; and
a second projecting portion formed to continue to the filling portion and project from the filling portion to the other side in the thickness direction.

2. The wired circuit board according to claim 1, wherein the first projecting portion continues to the wire.

3. A method of producing a wired circuit board, comprising the steps of:
forming an insulating layer formed with an insulating opening extending through the insulating layer in a thickness direction; and
forming a conductive pattern including a wire formed on the insulating layer and a terminal connected to the wire, wherein,
in the step of forming the conductive pattern, the conductive pattern is formed such that the terminal includes:
a filling portion with which the insulating opening of the insulating layer is internally filled;
a first projecting portion formed to continue to the filling portion and project from the filling portion to one side in the thickness direction; and
a second projecting portion formed to continue to the filling portion and project from the filling portion to the other side in the thickness direction.
